(19) United States
(12) Patent Application Publication
(10) Pub. No.: US 2013/0045596 A1
(43) Pub. Date: Feb. 21, 2013

(54) SEMICONDUCTOR DEVICE MANUFACTURING METHOD AND POLISHING APPARATUS

(71) Applicants: Hajime EDA, Yokohama-shi (JP); Yukiteru MATSUI, Yokohama-shi (JP)

(72) Inventors: Hajime EDA, Yokohama-shi (JP); Yukiteru MATSUI, Yokohama-shi (JP)

(21) Appl. No.: 13/428,494

(22) Filed: Mar. 23, 2012

(30) Foreign Application Priority Data
Aug. 19, 2011 (JP) 2011-179470

(51) Int. Cl. H01L 21/306; B24B 29/00; B24B 51/00

(52) U.S. Cl. 438/692; 451/7; 451/287; 257/E21.23

(57) ABSTRACT

According to one embodiment, a semiconductor device manufacturing method is provided. In the semiconductor device manufacturing method, a process target film is formed on a semiconductor substrate, and the surface of the process target film is polished by a CMP method. The CMP method comprises heating a rotating polishing pad from a first temperature to a second temperature higher than the first temperature, and bringing the surface of the process target film into contact with the polishing pad heated to the second temperature.

### CROSS-REFERENCE TO RELATED APPLICATIONS

This application is based upon and claims the benefit of priority from prior Japanese Patent Application No. 2011-179470, filed Aug. 19, 2011, the entire contents of which are incorporated herein by reference.

### FIELD

Embodiments described herein relate generally to a semiconductor device manufacturing method and a polishing apparatus.

### BACKGROUND

Recently, chemical mechanical polishing (CMP) is frequently used to planarize the surface in the step of forming multilayered interconnections or an element isolation in a semiconductor device. CMP is used to planarize a silicon oxide film to form an shallow trench isolation (STI) or planarize a tungsten, copper, or aluminum film to form contact plugs or interconnections.

CMP for next-generation devices are required to ensure high flatness, low defectiveness, and high productivity. As for the flatness, steps that directly lead to focus errors in lithography need to be reduced. As for the defectiveness, the defect density needs to be very low because the smaller the device is, the larger the influence of defects on the yield is. To improve the productivity, the polishing rate needs to be higher to shorten the process time.

CMP constituent elements that greatly meet the above-described requests are an abrasive slurry and a polishing pad. However, both constituent elements are expected to change the polishing characteristics along with a change in the temperature. In CMP, a desired temperature for higher polishing characteristics exists in accordance with the material to be polished.

To improve the polishing characteristics from the viewpoint of temperature, a method has been proposed in which a cooling mechanism is used to cool the abrasive slurry or the polishing pad and control them to a predetermined temperature during polishing. Use of the cooling mechanism also allows to control them to a desired temperature for higher polishing characteristics.

However, the temperature is low at the initial stage of polishing. The polishing characteristics vary until the temperature rises to the desired value for higher polishing characteristics. That is, in CMP, it is important to more quickly raise the temperature to the desired value and maintain the desired temperature.

### BRIEF DESCRIPTION OF THE DRAWINGS

FIGS. 1A, 1B, 1C, and 1D are sectional views showing the steps in the manufacture of interconnections in a semiconductor device according to an embodiment;

FIGS. 2A and 2B are sectional views showing the steps in the manufacture of an STI in the semiconductor device according to the embodiment;

FIG. 3 is a perspective view showing the arrangement of a CMP apparatus according to the embodiment;

FIGS. 4A, 4B, and 4C are graphs each showing the temperature dependence of the polishing rate of a process target film in CMP;

FIGS. 5A and 5B are a graph and a table, respectively, showing the temperature characteristics of a polishing pad 31 in a first CMP method according to the embodiment and comparative examples;

FIG. 6 is a table showing the relationship between the pressure of a heating mechanism 37 and the ultimate temperature of the polishing pad 31 in the CMP step according to the embodiment;

FIG. 7 is a graph showing the temperature characteristics of the polishing pad 31 when polishing a plurality of wafers by the first CMP method according to the embodiment; and

FIG. 8 is a graph showing the temperature transition of the polishing pad 31 in a second CMP method according to the embodiment.

### DETAILED DESCRIPTION

In general, according to one embodiment, a semiconductor device manufacturing method is provided. In the semiconductor device manufacturing method, a process target film is formed on a semiconductor substrate, and the surface of the process target film is polished by a CMP method. The CMP method comprises heating a rotating polishing pad from a first temperature to a second temperature higher than the first temperature, and bringing the surface of the process target film into contact with the polishing pad heated to the second temperature.

The embodiment will now be described with reference to the accompanying drawing. The same reference numerals denote the same parts throughout the drawing.

### [Method of Manufacturing Interconnection Structure and STI]

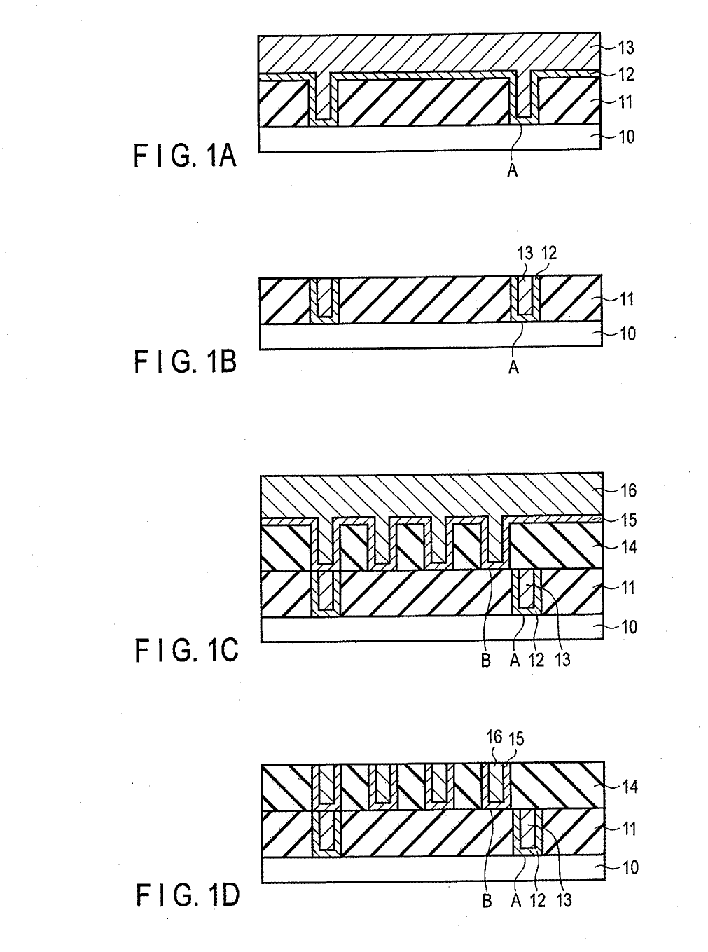

A method of manufacturing an interconnection structure and an STI in a semiconductor device according to the embodiment will be described below with reference to FIGS. 1A, 1B, 10, 1D, 2A, and 2B.

FIGS. 1A, 1B, 10, and 1D are sectional views showing the steps in the manufacture of interconnections in the semiconductor device according to the embodiment.

First, as shown in FIG. 1A, an insulating film 11 is formed on a semiconductor substrate 10 with a semiconductor element (not shown). The insulating film 11 is made of, for example, SiO₂. Contact holes A are formed in the insulating film 11. Next, a barrier metal 12 is formed on the entire surface. The barrier metal 12 is made of, for example, TiN. After that, a W film 13 serving as prospective contact plugs is formed on the entire surface by a conventional technique (for example, CVD). At this time, the W film 13 is formed even outside the contact holes A.

As shown in FIG. 1B, CMP is performed for the W film 13 and the barrier metal 12 that are films to be processed to planarize the surface. Details of the CMP step will be described later. The W film 13 and the barrier metal 12 outside the contact holes A are thus removed so that a contact layer including the insulating film 11, the barrier metal 12, and the W film 13 is formed. Note that not the W film 13 but a Cu film may be formed as the contacts.

As shown in FIG. 1C, an insulating film 14 is formed on the contact layer. The insulating film 14 is made of, for example, SiO₂. Interconnection grooves are formed as concave portions in the insulating film 14. A barrier metal 15 is formed on the entire surface by a conventional technique (for example, CVD). The barrier metal 15 is made of, for example, Ti. Next, a Cu film 16 serving as prospective interconnections is formed on the entire surface by a conventional technique (for example, CVD). At this time, the Cu film 16 is formed even outside the interconnection grooves B.

As shown in FIG. 1D, CMP is performed for the Cu film 16 and the barrier metal 15 that are films to be processed to planarize the surface. Details of the CMP step will be described later. The Cu film 16 and the barrier metal 15 outside the interconnection grooves B are thus removed so that an interconnection layer including the insulating film 14, the barrier metal 15, and the Cu film 16 is formed. Note that not the Cu film 16 but a W film may be formed as the interconnections.

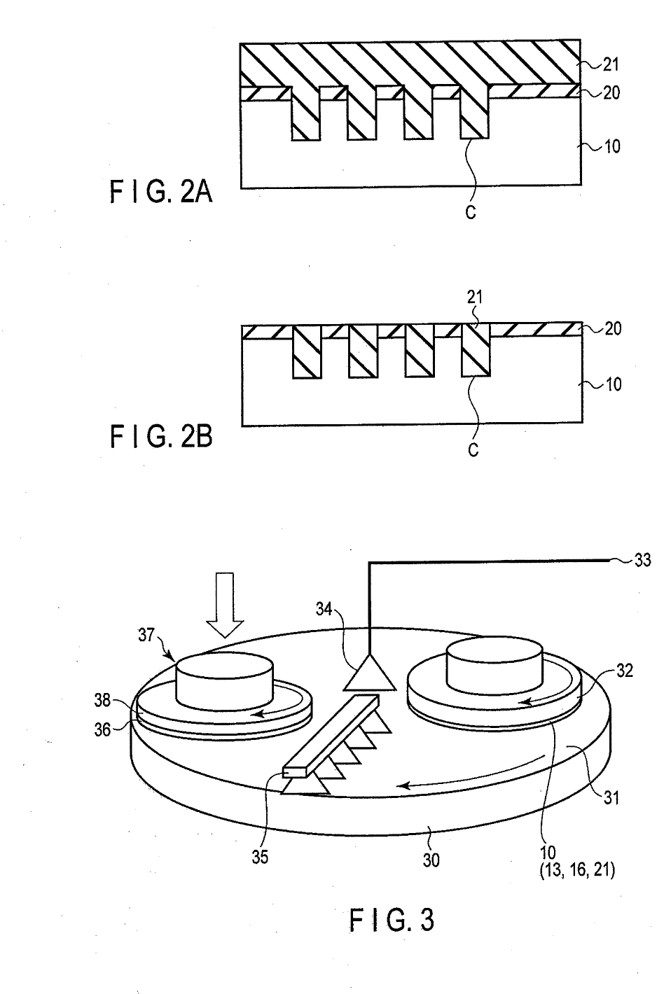

FIGS. 2A and 2B are sectional views showing the steps in the manufacture of an STI in the semiconductor device according to the embodiment.

First, as shown in FIG. 2A, a silicon nitride film 20 serving as a stopper film is formed on the semiconductor substrate 10. After that, an STI pattern C is formed in the semiconductor substrate 10 using a silicon oxide film or the like as an etching mask. Note that a silicon oxide film or the like may be provided between the semiconductor substrate 10 and the silicon nitride film 20.

Next, a silicon oxide film 21 is formed on the entire surface by, for example, high-density plasma CVD (HDP-CVD). At this time, the silicon oxide film 21 is formed even outside the STI pattern C.

As shown in FIG. 2B, CMP is performed for the silicon oxide film 21 that is a process target film to planarize the surface. Details of the CMP step will be described later. The silicon oxide film (SiO₂ film) 21 outside the STI pattern C is thus removed so that an STI structure is formed.

As described above, CMP is performed in the step for forming the interconnections or STI in the semiconductor device. The CMP step will be described below in detail. That is, in this embodiment, an example will be described in which the W film 13 or the Cu film 16 in the interconnection structure or the silicon oxide film 21 in the STI structure is used as the process target film to be processed by CMP. However, the embodiment is not limited to this and is applicable to CMP to be performed for films to be processed formed from various metal materials or insulating materials.

### [CMP Apparatus]

The arrangement of a CMP apparatus according to the embodiment will be described below with reference to FIG. 3.

FIG. 3 is a perspective view showing the arrangement of the CMP apparatus according to the embodiment.

As shown in FIG. 3, the CMP apparatus according to this embodiment comprises a turntable 30, a polishing pad 31, a polishing head 32, a slurry supply nozzle 33, a cooling nozzle 35, and a heating mechanism 37.

The polishing head 32 with the semiconductor substrate (wafer) 10 held on the surface is brought into contact with the polishing pad 31 bonded to the turntable 30. A process target film (for example, W film 13, Cu film 16, or silicon oxide film 21) is formed on the semiconductor substrate 10. That is, the process target film is polished by bringing the polishing head 32 into contact with the polishing pad 31.

The turntable 30 can rotate at 1 to 200 rpm. The polishing head 32 can rotate at 1 to 200 rpm. The turntable 30 and the polishing head 32 rotate in the same direction, for example, clockwise. However, the embodiment is not limited to this, and they may rotate in the reverse direction. Note that the turntable 30 and the polishing head 32 rotate in a predetermined direction during CMP. The pressure is normally about 50 to 500 hPa.

The slurry supply nozzle 33 is arranged on the polishing pad 31. The slurry supply nozzle 33 can supply a predetermined chemical solution serving as a slurry 34 at a flow rate of 50 to 500 cc/min. As the slurry 34, a chemical solution having a high polishing rate to the process target film is used. The slurry supply nozzle 33 is provided, for example, almost at the center of the turntable 30. However, the embodiment is not limited to this, and the slurry supply nozzle may appropriately be arranged to supply the slurry 34 to the entire surface of the polishing pad 31.

In addition, the cooling nozzle 35 for ejecting compressed air or nitrogen gas to the polishing pad 31 is arranged on the polishing pad 31. The cooling nozzle 35 is radially arranged on the polishing pad 31 about the slurry supply nozzle 33 (the rotating shaft of the turntable 30). For this reason, when the polishing pad 31 rotates, the cooling nozzle 35 can eject the compressed air or the like to the entire surface. The cooling nozzle 35 ejects the compressed air to the polishing pad 31 at about 0 to 1000 L/min. The cooling nozzle 35 can thus reduce and control the temperatures of the polishing pad 31 and the slurry 34 supplied to its surface.

In the CMP apparatus of this embodiment, the heating mechanism 37 is arranged on the polishing pad 31. The heating mechanism 37 has a function of generating a frictional heat by coming into contact with the polishing pad 31 while rotating, thereby raising the temperatures of the polishing pad 31 and the slurry 34 in the CMP step. The constituent elements of the heating mechanism 37 will be described below in detail.

The heating mechanism 37 includes a head portion 38 that can be rotated by a driving shaft, and a plate 36 held on the surface of the head portion.

The head portion 38 is connected to the driving shaft so as to be rotatable at 1 to 200 rpm. The driving shaft applies a force to the head portion 38 to bring it into contact with the polishing pad 31 at a pressure of 50 to 500 hPa. The rotating speed of the head portion 38 and the pressure to the polishing pad 31 can be adjusted as needed.

The plate 36 is held on the surface of the head portion 38 and rotates together with the head portion 38. In addition, the plate 36 comes into contact with the polishing pad 31 in accordance with the pressure of the head portion 38. That is, the driving shaft applies a force to the plate 36 to directly press it against the polishing pad 31.

The plate 36 is made of a hard material with a smooth surface, for example, a material containing carbon (C) and/or silicon (Si). Examples of the material containing carbon (C) and/or silicon (Si) are diamond and silicon carbide (SiC). However, the embodiment is not limited to this, and any other material whose polishing rate by the slurry 34 is less than that of the process target film and, preferably, 1/100 or less is usable. In this case, the plate 36 is not polished even when it comes into contact with the polishing pad 31 and the slurry 34 while rotating. In addition, the plate 36 is preferably made of a material that generates a large frictional force upon coming into contact with the polishing pad 31 to facilitate temperature rise of the polishing pad 31 and the slurry 34.

The plate 36 attached to the heating mechanism 37 has a smooth surface without abrasive grains and the like adhered to it. Hence, the plate 36 has no grinding capability for the polishing pad 31 and ensures low dust emission. That is, the heating mechanism 37 is different from a so-called dresser which has a surface with abrasive grains adhered and comes into contact with the polishing pad 31 while rotating, thereby grinding the surface of the polishing pad 31 and conditioning it. When coming into contact with the polishing pad 31, the heating mechanism 37 has no effect other than frictional heating (temperature rise) of the polishing pad 31.

Although the functions such as the polishing capability are different, the heating mechanism 37 of this embodiment performs the same basic operation as that of the dresser, that is, the heating mechanism 37 comes into contact with the polishing pad 31 while rotating. Hence, in a CMP apparatus having a dresser detachment function, the dresser may be replaced with the heating mechanism 37 of this embodiment.

As described above, according to the CMP apparatus of this embodiment, not only temperature control of cooling by the cooling nozzle 35 but also temperature control of heating by the heating mechanism 37 can be performed.

### [First CMP Method]

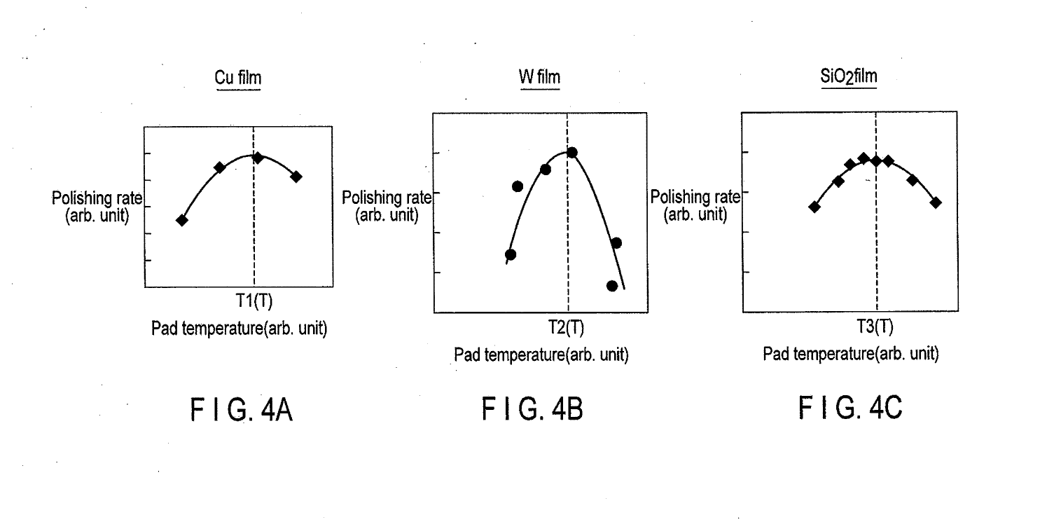

A first CMP method according to the embodiment will be described below with reference to FIGS. 4A, 4B, 4C, 5A, 5B, 6, and 7. Note that the verification result to be described below was obtained under the following conditions.

CMP apparatus: FREX300E available from Ebara Corporation

polishing pad: foaming pad (IC1000) available from Nitta Haas

abrasive slurry for oxide film: ceria slurry (DLS2) available from Hitachi Chemical

abrasive slurry for Cu film: silica slurry (CMS76xx-based) available from JSR

abrasive slurry for W film: silica slurry (W7573B) available from Cabot

polishing pad cooling method: high pressure air injection

polishing pad heating method: interfacial friction

FIGS. 4A, 4B, and 4C are graphs each showing the temperature dependence of the polishing rate of a process target film in CMP. More specifically, FIG. 4A shows a case in which the process target film is a Cu film, FIG. 4B shows a case in which the process target film is a W film, and FIG. 4C shows a case in which the process target film is an SiO₂ film.

As shown in FIGS. 4A, 4B, and 4C, normally, when the temperature of the polishing pad 31 rises, the polishing rate of the process target film rises in CMP. This is because when the temperature of the slurry 34 rises together with that of the polishing pad 31, the mechanical polishing force and chemical polishing force of the slurry 34 for the process target film become large.

However, when the temperature of the polishing pad 31 further rises and exceeds a temperature T (T1, T2, or T3), the polishing rate of the process target film decreases. This is because when the temperature of the polishing pad 31 exceeds a temperature T, the chemical polishing force of the slurry 34 for the process target film becomes smaller.

That is, to improve the productivity in CMP, it is important to perform CMP while setting the polishing pad 31 to the temperature T at which the polishing rate is maximized. Note that temperature T is about 20 to 70° C. although it changes depending on the material of the process target film, the polishing pad 31, or the slurry 34.

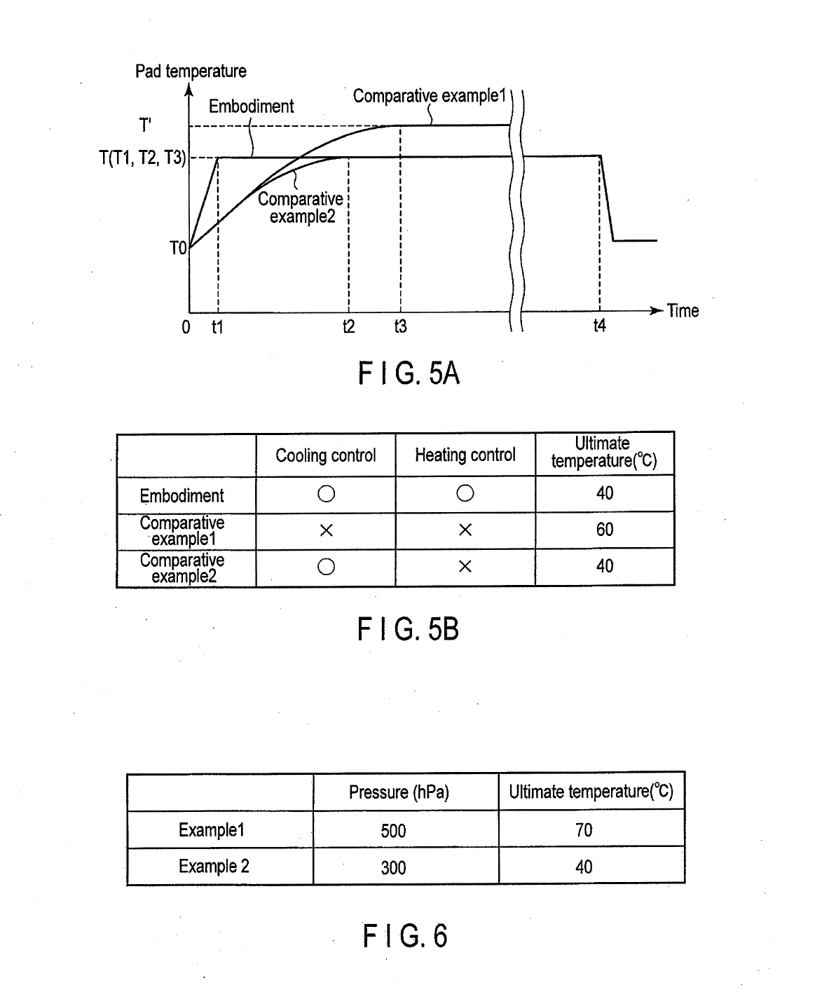

FIGS. 5A and 5B are a graph and a table, respectively, showing the temperature characteristics of the polishing pad 31 in the first CMP method according to the embodiment and comparative examples. More specifically, FIG. 5A is a graph showing the temperature transitions of the polishing pad 31 in the first CMP method according to the embodiment and comparative examples. FIG. 5B is a table showing the temperature control conditions of the polishing pad 31 in the first CMP method according to the embodiment and comparative examples.

Note that the process target film is not particularly limited in FIGS. 5A and 5B, and the method can similarly be applied to various materials.

As shown in FIGS. 5A and 5B, in Comparative Example 1, neither cooling control by the cooling nozzle 35 nor heating control by the heating mechanism 37 is performed. In this case, the polishing pad 31 is naturally heated from a temperature T0 to a temperature T′ (for example, 60° C.) by the friction between the polishing pad 31 and the polishing head 32 (process target film), and remains constant at temperature T′. Temperature T′ is higher than temperature T at which the polishing rate is high. In addition, heating the polishing pad 31 from temperature T0 to temperature T′ takes a time t3 longer than a time t1 to be described later. That is, according to Comparative Example 1, since ultimate temperature T′ is too high, and the time to reach ultimate temperature T′ is long, the productivity is low.

In Comparative Example 2, cooling control by the cooling nozzle 35 is performed, and heating control by the heating mechanism 37 is not performed. In this case, the polishing pad 31 is heated from temperature T0 to temperature T (for example, 40° C.) by the friction between the polishing pad 31 and the polishing head 32 (process target film) and the cooling control by the cooling nozzle 35, and remains constant at temperature T. At temperature T, the polishing rate is high. In addition, heating the polishing pad 31 from temperature T0 to temperature T takes a time t2 longer than time t1 to be described later. That is, according to Comparative Example 2, since the ultimate temperature is controlled by cooling control to temperature T at which the polishing rate is high, the productivity is higher than that of Comparative Example 1. However, since only cooling control is performed, control to raise the temperature to T cannot be performed, and the time to reach temperature T is long.

Conversely, in the first CMP method according to this embodiment, cooling control by the cooling nozzle 35 and heating control by the heating mechanism 37 are performed. In this case, the polishing pad 31 is heated from temperature T0 (room temperature: for example, 20° C.) to temperature T (for example, 40° C.) by the friction between the polishing pad 31 and the polishing head 32 (process target film), the heating control by the heating mechanism 37 (the friction between the polishing pad 31 and the heating mechanism 37), and the cooling control by the cooling nozzle 35, and remains constant at temperature T. In addition, heating the polishing pad 31 from temperature T0 to temperature T takes time t1 shorter than time t2.

That is, the temperature rise (rise from temperature T0 to temperature T) of the polishing pad 31 at the early stage of polishing in the first CMP method can be steeper than that of the polishing pad 31 at the early stage of polishing in Comparative Examples 1 and 2 because of the presence of not only the friction between the polishing pad 31 and the polishing head 32 but also heating control by the heating mechanism 37. At this time, time t1 is 25% or less of a time t4 until the end of the polishing step of the process target film (all steps of CMP). Note that Comparative Examples 1 and 2 at the end of polishing are not illustrated in FIG. 5A.

In the first CMP method, the heating mechanism 37 and the polishing head 32 (process target film) are in contact with the polishing pad 31 from the early stage (time 0) of the temperature rise of the polishing pad 31. That is, the temperature of the polishing pad 31 is raised by the frictional heat between the polishing pad 31 and the polishing head 32 and the frictional heat between the polishing pad 31 and the heating mechanism 37. Supply of the slurry 34 starts simultaneously with the timing the process target film comes into contact with the polishing pad 31, that is, from time 0.

FIG. 6 is a table showing the relationship between the pressure of the heating mechanism 37 and the ultimate temperature of the polishing pad 31 in the CMP step according to the embodiment. An example is shown in which an Si plate serving as the plate 36 is attached to the heating mechanism 37 and brought into contact with the polishing pad 31.

As described above, in this embodiment, the heating mechanism 37 shown in FIG. 3 is used as the heat source. That is, the frictional heat is generated in the contact surfaces of the heating mechanism 37 and the polishing pad 31 and conducted to the polishing pad 31, thereby raising the temperature of the polishing pad 31. At this time, changing the pressure of the heating mechanism 37 to the polishing pad 31 enables the ultimate temperature (temperature T in FIG. 4) of the polishing pad 31 to be changed.

More specifically, in Example 1, when the Si plate is brought into contact with the polishing pad 31 at a pressure of 500 hPa, the ultimate temperature of the polishing pad 31 is 70° C., as shown in FIG. 6. In Example 2, when the Si plate is brought into contact with the polishing pad 31 at a pressure of 300 hPa, the ultimate temperature of the polishing pad 31 is 40° C.

When the pressure of the plate 36 to the polishing pad 31 increases, the frictional force increases, and the ultimate temperature of the polishing pad 31 can be higher. On the other hand, when the pressure of the plate 36 to the polishing pad 31 decreases, the frictional force decreases, and the ultimate temperature of the polishing pad 31 can be lower. It is therefore possible to set the temperature of the polishing pad 31 in accordance with the material of the process target film to the optimum temperature at which the polishing rate is high. Note that the pressure of the plate 36 to the polishing pad 31 can be changed as needed even during the CMP operation, or the pressure can also be set to 0 (the plate 36 is separated from the polishing pad 31).

Not only changing the pressure of the plate 36 to the polishing pad 31 but also changing the rotating speed of the plate 36 (head portion 38) enables the ultimate temperature of the polishing pad 31 to be changed. More specifically, when the rotating speed of the plate 36 increases, the frictional force decreases, and the ultimate temperature can be lower. On the other hand, when the rotating speed of the plate 36 decreases, the frictional force increases, and the ultimate temperature can be higher.

That is, the ultimate temperature of the polishing pad 31 can be controlled by adjusting the frictional force between the plate 36 and the polishing pad 31. The frictional force is controlled by the pressure of the plate 36 to the polishing pad 31 and the rotating speed of the plate 36.

Not only the ultimate temperature of the polishing pad 31 but also the speed of temperature rise to the ultimate temperature can be controlled in a similar manner.

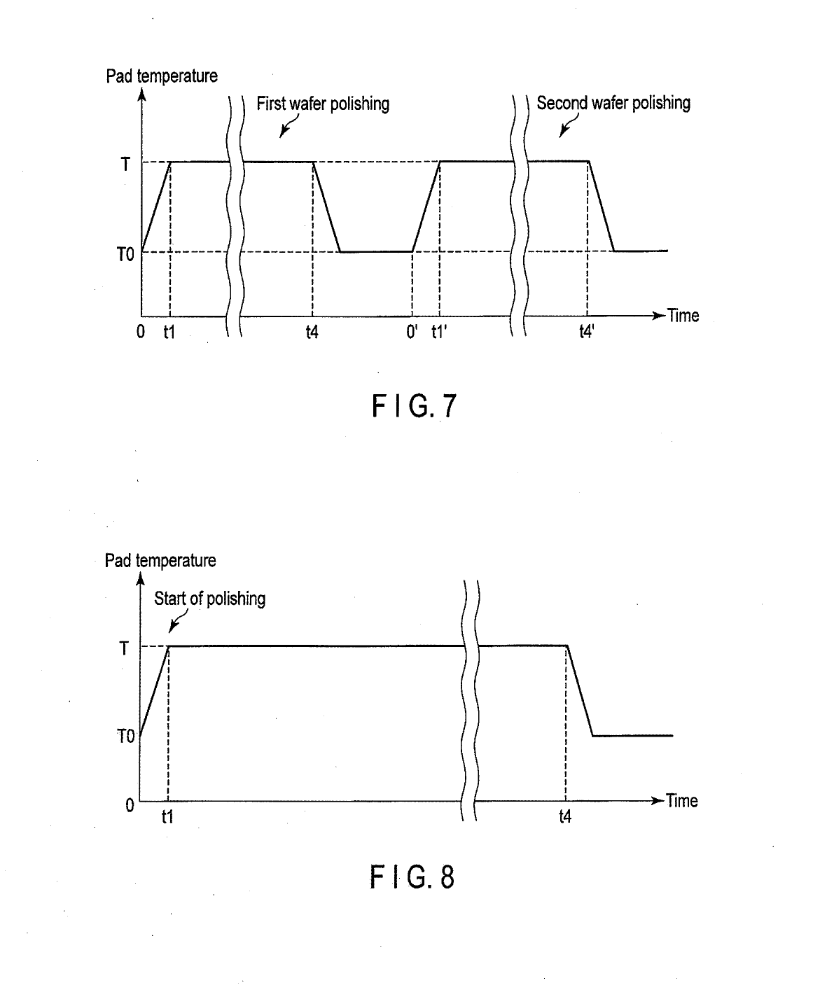

FIG. 7 is a graph showing the temperature characteristics of the polishing pad 31 when polishing a plurality of wafers by the first CMP method according to the embodiment.

As shown in FIG. 7, first, the process target film of a first wafer is polished up to time t4. At this time, the same temperature control as in the CMP shown in FIG. 5 is performed. After that, the heating mechanism 37 is replaced with a dresser to condition the surface of the polishing pad 31. The temperature of the polishing pad 31 thus decreases to as in the initial stage of polishing of the first wafer.

Abrasive grains are adhered to the surface of the dresser. The dresser comes into contact with the polishing pad 31 while rotating, thereby grinding the surface of the polishing pad 31 and conditioning it. The conditioning is performed while supplying, for example, pure water at room temperature to remove grinding residues of the surface of the polishing pad 31. That is, since the heated surface of the polishing pad 31 is ground and removed by the conditioning, the temperature of the polishing pad 31 lowers to T0 without rising.

Next, the process target film of a second wafer is polished. That is, as shown in FIG. 7, even at the start (time 0′) of polishing of the process target film of the second wafer, the temperature of the polishing pad 31 is T0, as in the start (time 0) of polishing of the first wafer. For this reason, the same temperature control as in polishing the process target film of the first wafer is performed when polishing the process target film of the second wafer as well. That is, the polishing pad 31 is heated to temperature T from a time 0′ to a time t1′, and the process target film is polished up to time t4′. At this time, the time from time 0′ to time t1′ is 25% or less of the time (the time from time 0′ to time t4′) until the end of the polishing step of the process target film of the second wafer (all steps of CMP of the process target film of the second wafer).

Note that when polishing a plurality of wafers, the temperature of the polishing pad 31 may be maintained at T by operating the heating mechanism 37 during conditioning of the surface of the polishing pad 31 by the dresser (during the time from time t4 to time 0′). This allows to polish the second wafer without temperature transition of the polishing pad 31. However, when the polishing pad 31 maintains the high temperature (temperature T), the polishing characteristics of the polishing pad 31 may degrade. To prevent this, the temperature is preferably temporarily reduced to T0 between the first wafer polishing and the second wafer polishing, as shown in FIG. 7.

### [Effects of First CMP Method]

According to the first CMP method, the heating mechanism 37 performs heating control of the polishing pad 31. This makes it possible to quickly raise the temperature of the polishing pad 31 from initial temperature T0 to temperature T at which the polishing rate is high at the early stage of polishing of the process target film. Hence, the productivity in CMP can be improved.

More specifically, time t1 to raise the temperature of the polishing pad 31 from initial temperature T0 to temperature T at which the polishing rate is high is reduced to 25% or less of time t4 until the end of the polishing step of the process target film (all steps of CMP). This allows to shorten the polishing time by about 10% as compared to Comparative Example 2 shown in FIG. 5.

Cooling control by the cooling nozzle 35 is also performed together with heating control by the heating mechanism 37. This enables the temperature of the polishing pad 31 to be more precisely controlled. That is, not only the productivity but also the other polishing characteristics can be improved.

### [Second CMP Method]

A second CMP method according to the embodiment will be described below with reference to FIG. 8. Note that for the second CMP method, a description of the same points as in the first CMP method will be omitted, and different points will be explained.

FIG. 8 is a graph showing the temperature transition of the polishing pad 31 in the second CMP method according to the embodiment.

Note that the process target film is not particularly limited in FIG. 8, and the method can similarly be applied to various materials. In addition, times 0, t1, and t4 shown in FIG. 8 are not necessarily the same as those shown in FIGS. 5A, 5B and 7.

In the second CMP method according to this embodiment, cooling control by the cooling nozzle 35 and heating control by the heating mechanism 37 are performed. In this case, the polishing pad 31 is heated from temperature T0 to temperature T (for example, 40° C.) and remains constant at temperature T by the heating control by the heating mechanism 37 (the friction between the polishing pad 31 and the heating mechanism 37) and the cooling control by the cooling nozzle 35.

In the second CMP method, only the heating mechanism 37 is brought into contact with the polishing pad 31 during the time from the early stage of temperature rise of the polishing pad 31 to the arrival of the polishing pad 31 at the predetermined temperature T (during the time from time 0 to time t1). That is, the polishing head 32 (process target film) is not in contact with the polishing pad 31. For this reason, the temperature of the polishing pad 31 rises solely because of the frictional heat between the polishing pad 31 and the heating mechanism 37. From time t1 the polishing pad 31 is heated to temperature T, the process target film comes into contact with the polishing pad 31, and polishing starts. That is, the polishing pad 31 remains at the predetermined temperature T from the beginning when polishing of the process target film starts. At this time, supply of the slurry 34 starts simultaneously with bringing the process target film into contact with the polishing pad 31, that is, from time t1.

### [Effects of Second CMP Method]

According to the second CMP method, the heating mechanism 37 performs heating control before polishing of the process target film to raise the temperature of the polishing pad 31 from initial temperature T0 to temperature T at which the polishing rate is high. After the polishing pad 31 has been heated to temperature T, the process target film is brought into contact with the polishing pad 31, and polishing starts. That is, it is possible to polish the process target film while maintaining the polishing pad 31 at temperature T at which the polishing rate is high. Hence, the productivity in CMP can be improved.

More specifically, applying the second CMP method to CMP of the Cu film 16 when time t1 (temperature rise time) is 30 sec allows to shorten the polishing time by about 10% as compared to Comparative Example 2 shown in FIG. 5.

In addition, according to the second CMP method, the process target film is polished while maintaining the polishing pad 31 constant at temperature T. That is, the temperature of the polishing pad 31 does not change during polishing of the process target film. This allows to suppress the change in the polishing characteristics caused by the temperature change during polishing of the process target film.

Furthermore, according to the second CMP method, the slurry 34 is used after the polishing pad 31 has been heated to temperature T. That is, supply of the slurry 34 is performed at temperature T at which the polishing rate is high. For this reason, out of the supply time of the slurry 34, the time the processing is performed at the high polishing rate increases. Actually, the polishing rate is high throughout the supply time of the slurry 34. This enables the amount of slurry 34 used to be decreased.

While certain embodiments have been described, these embodiments have been presented by way of example only, and are riot intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device manufacturing method comprising:
forming a process target film on a semiconductor substrate; and
polishing a surface of the process target film by a CMP method,
wherein the CMP method comprises:
heating a rotating polishing pad from a first temperature to a second temperature higher than the first temperature; and
bringing the surface of the process target film into contact with the polishing pad heated to the second temperature.

2. The method of claim 1, wherein a polishing rate of the process target film at the second temperature is higher than that at the first temperature.

3. The method of claim 1, wherein in the bringing the surface of the process target film into contact with the polishing pad, the polishing pad remains constant at the second temperature.

4. The method of claim 1, wherein the CMP method further comprises supplying a slurry to a surface of the polishing pad after heating the polishing pad to the second temperature.

5. The method of claim 1, wherein the process target film is one of a Cu film, a W film, and an SiO₂ film.

6. The method of claim 1, wherein the second temperature ranges from 20 to 70° C.

7. A semiconductor device manufacturing method comprising:
forming a process target film on a semiconductor substrate; and
polishing a surface of the process target film by a CMP method,
wherein the CMP method comprises:
heating a rotating polishing pad from a first temperature to a second temperature higher than the first temperature; and
bringing the surface of the process target film into contact with the polishing pad, and
the heating the polishing pad from the first temperature to the second temperature is performed in a time not more than 25% of a time of all steps of the CMP method.

8. The method of claim 7, wherein a polishing rate of the process target film at the second temperature is higher than that at the first temperature.

9. The method of claim 7, wherein, the heating the polishing pad from the first temperature to the second temperature and the bringing the surface of the process target film into contact with the polishing pad start simultaneously.

10. The method of claim 9, wherein the CMP method further comprises supplying a slurry to a surface of the polishing pad simultaneously with the heating the polishing pad from the first temperature to the second temperature and the bringing the surface of the process target film into contact with the polishing pad.

11. The method of claim 7, wherein the process target film is one of a Cu film, a W film, and an SiO₂ film.

12. The method of claim 7, wherein the second temperature ranges from 20 to 70° C.

13. A polishing apparatus comprising:
a rotating polishing pad;
a slurry supply nozzle configured to supply a slurry to the polishing pad;
a polishing head configured to hold a process target film on a surface and polish the process target film by coming into contact with the polishing pad; and
a heating mechanism having, on a surface, a plate made of a material whose polishing rate by the slurry is lower than that of the process target film and configured to heat the polishing pad by coming into contact with the polishing pad while rotating.

14. The apparatus of claim 13, further comprising a cooling nozzle configured to reduce a temperature of the polishing pad.

15. The apparatus of claim 13, wherein the plate has a smooth surface without abrasive grains adhered.

16. The apparatus of claim 13, wherein the heating mechanism controls temperature rise of the polishing pad by adjusting a rotating speed and a pressure to the polishing pad.

17. The apparatus of claim 14, wherein the cooling nozzle reduces the temperature of the polishing pad by ejecting one of compressed air and nitrogen gas to the polishing pad.

18. The apparatus of claim 13, wherein the material contains C and/or Si.

19. The apparatus of claim 18, wherein the material contains one of diamond and SiC.

20. The apparatus of claim 13, wherein the polishing rate of the material by the slurry is not more than 1/100 the polishing rate of the process target film by the slurry.
